(19) United States
(12) Patent Application Publication
(10) Pub. No.: US 2001/0045352 A1
(43) Pub. Date: Nov. 29, 2001

(54) Sputter deposition using multiple targets

(76) Inventors: Raymond S. Robinson, Ft. Collins, CO (US); Viacheslav V. Zhurin, Ft. Collins, CO (US); James R. Kahn, Ft. Collins, CO (US); Harold R. Kaufman, LaPorte, CO (US)

Correspondence Address: Dean P. Edmundson, P.O. Box 710, Windsor, CO, 80550, US

(21) Appl. No.: 09/881,116

(22) Filed: Jun. 13, 2001

Related U.S. Application Data
(63) Continuation-in-part of application No. 09/471,662, filed on Dec. 23, 1999.
Application No. 09/471,662 is a continuation-in-part of application No. 09/078,727, filed on May 14, 1998, now abandoned.

(51) Int. Cl. C23C 14/46

(52) U.S. Cl. 204/192.11; 204/298.04; 204/298.03; 204/192.13

(57) ABSTRACT

In accordance with one specific embodiment of the present invention, an ion-beam deposition apparatus uses a plurality of stationary sputter targets so located so as to provide a predetermined thickness distribution of the target material on a substrate. This distribution is obtained without mechanical motion of ion sources, sputter targets, or a shaper located between the sputter targets and deposition substrate.

In accordance with another embodiment, a sputter deposition apparatus uses a plurality of targets, with sputter deposition from different targets initiated and terminated in a controlled manner so as to deposit a layered structure. This layered structure is obtained without mechanical motion of ion sources, sputter targets, or a shaper located between the sputter targets and deposition substrate.

CROSS-REFERENCE TO RELATED APPLICATION

This application is a continuation-in-part of our copending application Ser. No. 09/471,662, filed Dec. 23, 1999, which was a continuation-in-part of our earlier application Ser. No. 09/078,727, filed May 14, 1998, now abandoned.

### FIELD OF INVENTION

This invention relates generally to the deposition of thin films, and more particularly to the sputter deposition of thin films and the control of the thickness distributions of single or multiple constituents in the films deposited in this manner.

This invention can find application in a variety of thin film applications such as the deposition of decorative or protective films, the deposition of dielectric films for optical devices, the deposition of conducting or dielectric films for solid state electronics, or the deposition of magnetic films for recording heads or recording media.

### BACKGROUND

Beams of energetic ions have been used to sputter deposit thin films in a variety of industrial applications. A typical apparatus includes an electrostatically accelerated ion beam directed at a sputter target. The sputtered material is deposited on a substrate. For the deposited film to be free of contamination, the ion beam must be accurately directed at the sputter target. This is because, if the energetic ion beam strikes other hardware in the surrounding vacuum chamber, sputtered material from the other hardware will contaminate the deposited film. The thickness distribution of the deposited film can be important, with the usual objective a uniform film thickness. If multiple targets are used, mechanical motion is used to move them in or out of the ion beam. The most widely used type of ion source for such a sputter-deposition application is the gridded ion source described in an article by Kaufman, et al., in the AIAA Journal, Vol. 20 (1982), beginning on page 745, incorporated herein by reference.

Our copending application Ser. No. 09/471,662, filed Dec. 23, 1999 describes another apparatus that uses an ion source for sputter deposition. In this case the ions have energies near to, or less than, the sputtering threshold, and the energy required for sputtering is obtained by biasing the sputter target negative relative to ground, which is typically at the potential of the surrounding vacuum chamber. An important difference from the previous apparatus is the absence of any need for accurate direction of the ions, due to the use of low ion energies. The end-Hall type of gridless ion source is described in U.S. Pat. No 4,862,032—Kaufman, et al., is well suited for use as a low-energy ion source.

In using ion beams to sputter deposit films, the objective is typically to deposit a film with a predetermined distribution of film thickness, usually one with a uniform thickness. The sputter deposition from a target is, however, inherently nonuniform. The easiest way to make the film more uniform is to locate the deposition substrate at a large distance from the target. For small to moderate size sputter targets, the region of uniformity increases approximately linearly with distance from the target. For example, the width of the uniform region can be about doubled if the substrate is placed twice as far from the target. The deposition rate, though, varies approximately as the inverse-square of distance from the target. That is, the deposition rate would drop by approximately a factor of four if the target were placed twice as far from the target. Using increased distance to increase the size of the uniform region can thus result in a substantial decrease in process rate.

An added complication in obtaining a deposited film of uniform thickness is the development of a texture on the target. Such a texture will result in a change in the angular distribution of material sputtered from the target. This change in angular distribution can in turn result in a change in the thickness distribution of the deposited film, displacing the uniform region toward the ion source, when the source generates a beam of energetic ions. A fairly common technique to compensate for the development of a texture on the target is to provide a range of adjustment for the angle of the target relative to the incident ions.

An increase in the size of the region of uniform film deposition has been obtained with the use of a “shaper,” which is located in a fixed position between the sputter target and the deposition substrate and mechanically blocks some of the sputtered material leaving the target. For this blocking to result in uniform deposition, there must be relative motion between the shaper and the deposition substrate, which is usually obtained by rotating the substrate. The uniformity obtained in this manner, however, can be adversely affected by changes in surface texture on the target. This shortcoming is in addition to the need for mechanical motion (rotation) of the substrate.

It is also possible to keep the substrate fixed and move the shaper. This approach is described in U.S. Pat. No. 6,197,164 B1—Pinarbasi.

Uniform deposition has also been obtained with substrates that are moved over complicated paths through the sputtered efflux from the target, in order to average the deposition on different substrates. A “planetary” substrate stage is an example of the apparatus used to achieve this averaging. While this approach can increase production by increasing the number of substrates processed at one time, it does nothing to increase uniformity over a large substrate.

### SUMMARY OF INVENTION

In light of the foregoing, it is an overall general object of the invention to provide a sputter deposition apparatus in which multiple target areas are used to achieve a controlled distribution of deposition thickness over an extended substrate area.

A more specific object of the present invention is to provide an ion-beam deposition apparatus in which the development of a surface texture on the target has a reduced effect on the distribution of substrate thickness.

A further object of the present invention is to provide a sputter deposition apparatus in which little or no mechanical motion is required to achieve a desired distribution of deposition uniformity over an extended substrate area.

Yet another object of the present invention is to provide a sputter deposition apparatus in which the sputtering from multiple target areas can be controlled electrically at the targets without interrupting ion source operation.

Still another object of the present invention is to provide a sputter deposition apparatus in which control of the distribution of deposition thickness is obtained without the use of a shaper between the sputter targets and the deposition substrates.

In accordance with one specific embodiment of the present invention, an ion-beam deposition apparatus uses a plurality of stationary or non-moving sputter targets located so as to provide a predetermined thickness distribution of the target material on a substrate. This distribution is obtained without mechanical motion of ion sources, sputter targets, or a shaper located between the sputter targets and deposition substrate.

In accordance with another embodiment, a sputter deposition apparatus uses a plurality of targets, with sputter deposition from different targets initiated and terminated in a controlled manner so as to deposit a layered structure. This layered structure is obtained without mechanical motion of ion sources, sputter targets, or a shaper located between the sputter targets and deposition substrate.

### DESCRIPTION OF FIGURES

Features of the present invention which are believed to be patentable are set forth with particularity in the appended claims. The organization and manner of operation of the invention, together with further objectives and advantages thereof, may be understood by reference to the following descriptions of specific embodiments thereof taken in connection with the accompanying drawings, in the several figures of which like reference numerals identify like elements and in which:

FIG. 1 shows a prior-art ion-beam deposition apparatus with the trajectories of energetic ions and sputtered atoms or molecules indicated schematically;

FIG. 2a shows a cross-sectional view of a small portion of the sputter target shown in FIG. 1;

FIG. 2b indicates the angular distribution of sputtered material from the sputter-target portion shown in FIG. 2a;

FIG. 3a shows a cross-sectional view of a small portion of the sputter target shown in FIG. 1 upon which a textured topography has developed;

FIG. 3b indicates the angular distribution of sputtered material from the sputter-target portion shown in FIG. 3a;

FIG. 4 shows the prior-art ion-beam deposition apparatus of FIG. 1 with pertinent dimensions indicated;

FIG. 5 depicts the variation of deposition thickness obtained with the prior-art ion-beam deposition apparatus indicated in FIGS. 1 and 4 using sputter targets with both smooth and textured surfaces;

FIG. 6 depicts the variation of deposition thickness obtained with the prior-art ion-beam deposition apparatus indicated in FIGS. 1 and 4 using smooth sputter targets with sputtered regions of various diameters;

FIG. 7 shows the prior-art ion-beam deposition apparatus of FIGS. 1 and 4 with different possible substrate locations;

FIG. 8 shows a prior-art ion-beam deposition apparatus similar to that shown in FIGS. 1 and 4 with the addition of a shaper between the sputter target and the deposition substrate;

FIG. 9 shows the top view of the prior-art ion-beam deposition apparatus shown in FIG. 8;

FIG. 10 depicts the variation of deposition thickness obtained with the prior-art ion-beam deposition apparatus indicated in FIGS. 8 and 9 using a smooth sputter target;

FIG. 11 shows a sputter deposition apparatus constructed in accordance with a specific embodiment of the present invention;

FIG. 12 depicts the variation of deposition thickness obtained with the sputter deposition apparatus of FIG. 11 using sputter targets with a moderate amount of texturing and showing both the individual and combined contributions from both targets;

FIG. 13 depicts the variation of deposition thickness obtained with the sputter deposition apparatus of FIG. 11 using both smooth and highly textured sputter targets and an enlarged scale compared to FIG. 12;

FIG. 14 shows an ion-beam deposition apparatus constructed in accordance with another specific embodiment of the present invention;

FIG. 15 depicts the variation of deposition thickness obtained with the ion-beam deposition apparatus of FIG. 14 using smooth sputter targets and showing both the individual and combined contributions from both targets;

FIG. 16 depicts the departure from the variation of deposition thickness at X/S=0, obtained with the ion-beam deposition apparatus of FIG. 14 using smooth sputter targets and an enlarged scale compared to FIG. 15;

FIG. 17 shows an ion-beam deposition apparatus constructed in accordance with yet another specific embodiment of the present invention;

FIG. 18 shows the top view of the ion-beam deposition apparatus shown in FIG. 17;

FIG. 19 depicts the maximal and minimal radial variations of deposition thickness obtained with the ion-beam deposition apparatus of FIGS. 17 and 18 using smooth sputter targets;

FIG. 20 shows an ion-beam deposition apparatus constructed in accordance with a specific embodiment of the present invention that is similar to that shown in FIGS. 17 and 18, except for the use of small sputter targets and these sputter targets being at an angle α relative to a coplanar location;

FIG. 21 depicts the optimum ratio of target location radius to target-substrate spacing as a function of the angle α for the ion-beam deposition apparatus of FIG. 20;

FIG. 22 depicts the ratio of uniform-deposition radius to optimum target location radius as a function of the angle α for the ion-beam deposition apparatus of FIG. 20;

FIG. 23 depicts the relative deposition rate using the optimum target radius as a function of the angle α for the ion-beam deposition apparatus of FIG. 20;

FIG. 24 shows a composite sputter target suitable for use in the ion-beam deposition apparatuses of FIGS. 11, 14, 17, and 20;

FIG. 25 shows an enlarged, cross-sectional view of the composite sputter target shown in FIG. 24 along section A-A therein plus a shield which surrounds the target and is not shown in FIG. 24; and

FIG. 26 shows a schematic diagram of an active control for an apparatus similar to that shown in FIG. 14.

### DESCRIPTION OF PRIOR ART

Referring to FIG. 1, there is shown prior-art ion-beam deposition apparatus 100. The ion-beam deposition is carried out in evacuated volume 91 enclosed by vacuum chamber 90. The chamber is pumped through port 92 to reach the operating pressure, as well to maintain that pressure during deposition. The evacuated chamber is usually electrically connected to earth ground 93. An ionizable gas (not shown) is introduced into ion source 101, which generates energetic ion beam 102. The ion beam is directed at sputter target 103, striking exposed surface 104 of target 103. Sputtered atoms or molecules 105 leave target 103, some of which strike substrate 106 and are deposited to form a film on exposed surface 107 of the substrate. The ion source most widely used to generate the energetic ion beam in such a deposition apparatus is described in the aforementioned article by Kaufman, et al., in the AIAA Journal, Vol. 20 (1982), beginning on page 745. For longer operation without maintenance or operation with reactive gases, a radiofrequency discharge can be used instead of the direct-current discharge described therein.

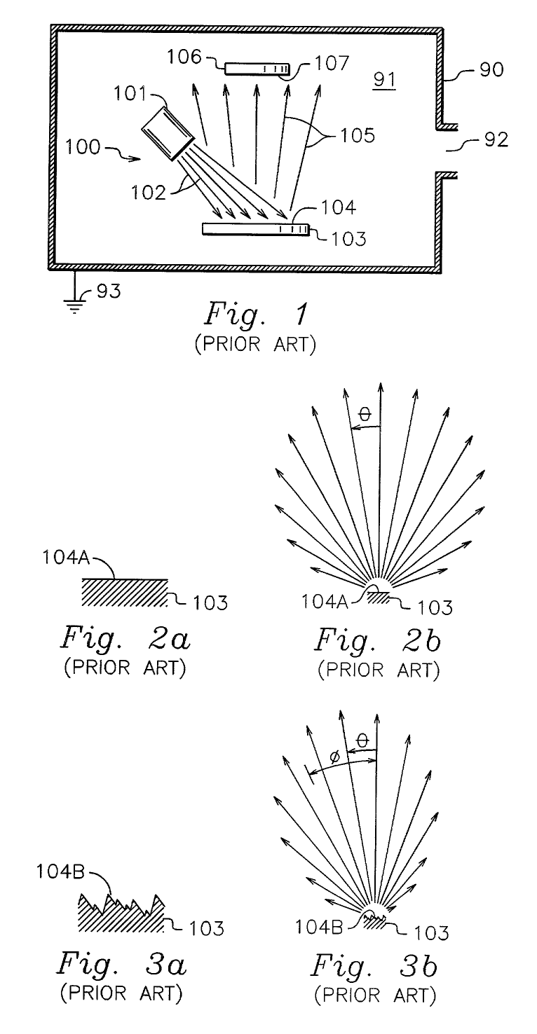

Referring to FIG. 2a, there is shown an enlarged cross section of a small portion of target 103, showing portion 104A of surface 104. As is typical of new targets, the topography of portion 104A is smooth. It should be mentioned that the target may be of a crystalline structure, but that the bombardment by energetic ions rapidly makes the surface layer amorphous under most deposition conditions, even though the surface may remain smooth after this layer becomes amorphous.

Referring to FIG. 2b, there is shown a graphical depiction of the angular distribution of sputtering intensity from the target portion shown in FIG. 2a. As described by Wehner, et al., in Chapter 3 of Handbook of Thin Film Technology (Maissel and Glang, eds.), McGraw-Hill Book Company, New York, 1970, a cosine distribution is a common representation of the sputtering intensity distribution. That is, the intensity, I, follows the relationship

I=Iₒcos θ, (1)

where θ is the angle measured relative to the normal from the surface and Iₒ is the intensity in the normal (θ=0) direction. The amorphous structure of the surface layer from which the sputtered atoms or molecules come is generally assumed for the above equation.

Referring to FIG. 3a, there is shown another enlarged cross section of a small portion of target 103, showing portion 104B of surface 104 after a prolonged period of bombardment by ion beam 102. As is fairly common for such targets, the topography of portion 104B is textured. The most common texture is a large number of small cones of various sizes, with the apexes of the cones pointing generally toward the source of energetic ions.

The angular distribution of sputtered material from the textured surface of surface portion 104B is indicated graphically in FIG. 3b. The texturing both narrows the distribution and moves the maximum intensity toward the direction from which the incident ions arrive. The angular distribution from a well-developed textured surface is approximated herein by

I=Iₒcos θ cosⁿ(θ+ø)/cosⁿø, (2)

where the 1/cosⁿø is required to normalize Iₒ to unity. The angle θ=ø is the angular offset of the sputter distribution due to texturing and is assumed here to be in the direction of the incident ions. The exponent n can adjust for the magnitude of the texturing effect. For a smooth target, n=0 is used.

Whether or not a texture develops on surface 104 depends on the target material and temperature. A texture is more likely to develop on a target that is an alloy or compound, rather than a single element. It is also more likely if the target is operated at a high temperature.

It should also be pointed out that the distributions of FIGS. 2b and 3b and equations (1) and (2) are not exact, but can vary with the material being sputtered, the ions used for the sputtering, the incident angle of the ions on the target, and the energy of those ions. The effects described should therefore be considered exemplar of those actually encountered in practical applications of the prior art.

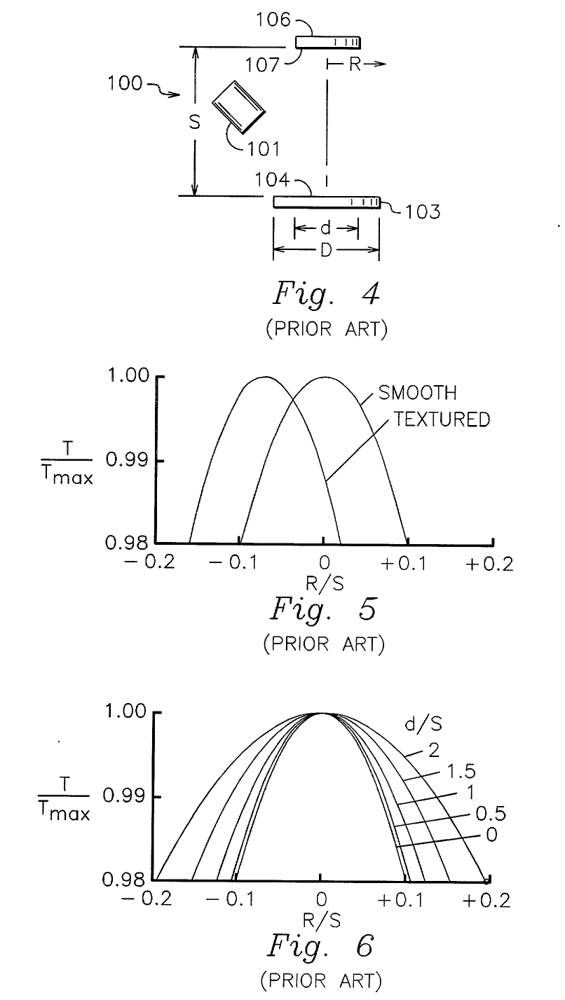

The prior-art ion-beam deposition apparatus shown in FIG. 1 is also shown in FIG. 4, with the ion beam and sputtered material omitted in order to better show pertinent dimensions. Sputter target surface 104 is shown parallel to substrate deposition surface 107, with the two surfaces spaced a distance S apart. The target has a diameter D. The ion beam does not have a sharp edge, but gradually tapers off. It is important that other hardware is not sputtered by the edge of the ion beam, which would add contamination to the deposited film. To avoid such contamination, the bulk of the ion beam is confined to a diameter d that is substantially smaller than target diameter D.

Because ion source 101 must not intercept sputtered material as it travels from target surface 104 to substrate surface 107, it must be located to the side, as shown in FIGS. 1 and 4. This side location results in the angular displacement of the texturing shown in FIG. 3a and an angular displacement of the sputtered material relative to the distribution of sputtered material from a smooth target—as indicated in both FIG. 3b and equation (2).

To obtain the thickness distribution of the deposited film, it is necessary to introduce another cosine θ for the angle of the substrate surface relative to the trajectory of the sputtered particles. The thickness distribution from a small portion of target surface is thus

T=Tₒcos²θ cosⁿ(θ−ø)/cosⁿø. (3)

Note that the reference thickness Tₒ occurs at θ=ø. The maximum film thickness also occurs at θ=0 for ø=0, but occurs at an angle θ≠0 for ø≠0.

Equation (3) is valid for only a single small portion of target area, but, as will be shown, is a close approximation when integrated over the surface of targets of moderate size. Assuming such a moderate target size for the apparatus in FIGS. 1 and 4, equation (3) was used to calculate the distributions of deposition thickness that is shown in FIG. 5. For a “Smooth” target, n=0. For a “Textured” target, moderate values of n=1 and ø=20 degrees were used.

Uniformity requirements frequently approach or exceed ±1 percent, which corresponds to the thickness range from 0.98 to 1.00 of maximum thickness shown in FIG. 5. From FIG. 5, a ±1 percent requirement for the prior-art ion-beam apparatus in FIGS. 1 and 4 would, using a smooth target, only be met for a region within a radius of only 0.1 S of the axis of symmetry. For a requirement of ±0.5 percent, the radius would be reduced to 0.07 S. As described in the background section, the size of the uniform region can be increased by increasing the substrate-target distance S, but the deposition rate would vary as 1/S².

For the textured target, the size of the uniform region was reduced slightly by the introduction of the cos(θ+ø) texturing term, but the more significant effect was the transverse displacement of the uniform region due the offset ø. At the 99 percent of maximum level, this transverse displacement is slightly greater than the radius of the uniform region. It should be clear that the development of a texture on the target can be a serious problem in the deposition of uniform film thicknesses. The usual technique for offsetting the shift shown in FIG. 5 is to tilt the target slightly as a texture develops. That is, to use mechanical motion to offset the morphology change on the target surface.

Referring to FIG. 6, there is shown the effect of increasing the effective diameter of the ion beam d on a smooth target. For a finite region of sputtering, equation (3) can be used, with n=0, for each target portion, but the deposition contributions from all target portions must be summed to obtain the overall contribution,

T/Tₘₐₓ=ΣIₒcos²θ/[ΣIₒcos²θ]_{R=0}. (4)

From symmetry considerations, T/Tₘₐₓ=1 at R=0. To avoid the use of specific beam profiles, the sputtering rate was assumed to be uniform over beam diameter d on the target. A 25-point approximation was used for the finite target size, with each point representing an equal sputtered area of the target. A comparison of results using the 25-point approximation with those obtained using a 9-point approximation showed only small differences, indicating that the 25-point approximation should be sufficiently accurate for the calculations herein.

In FIG. 6, there is little effect of ion beam diameter (the size of the sputtered region) for ratios of d/S<1. A beam diameter d equal to the substrate-target spacing S is a large sputtering region, which means that, for moderate target sizes, a point target (d/S=0) gives a good approximation for most calculations. In practice, the diameter D of a sputter target used with an energetic ion beam is determined more from the need to fully capture the ion-beam profile and thereby assure purity of the deposited film, than from considerations of deposition thickness distribution.

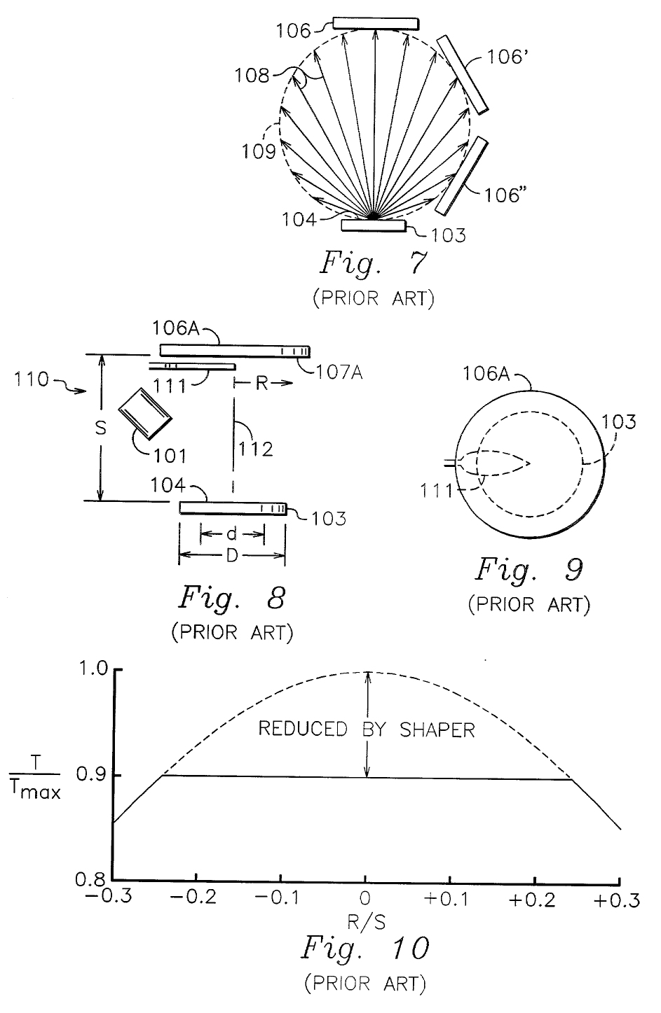

The preceding discussion of FIGS. 1 through 6 assumes axisymmetric arrangements of sputter regions and deposition substrates without relative motion between the two. A prior-art deposition apparatus similar to that shown in FIGS. 1 and 4 is shown in FIG. 7 with different possible substrate locations. The location of substrate 106 duplicates the configurations of FIGS. 1 and 4. Substrate 106′ is at a substantial angle compared to that of substrate 106, while substrate 106″ is at an even greater angle. Except for interference with the ion source (not shown in FIG. 7), substrates could have been shown on the left side of FIG. 7 at various angles from the original location of substrate 106. The sputtering is assumed to originate from a small area of surface 104 of sputter target 103. The distribution of sputter intensities is shown by the length of arrows 108. The locus of the ends of these arrows is shown by dashed line 109, which, in three dimensions, is approximately a sphere. (For a cosine distribution from a point source of sputtered particles, dashed line 109 would be precisely a sphere.) Everywhere on dashed line 109, the deposition rate is the same. It should be apparent that, not only will the deposition rate be the same for substrates 106, 106′, and 106″, but the uniformities will also be the same for the deposited films as long as the substrates are tangent to the same sphere.

There are practical considerations that limit the choice of substrate locations. As mentioned, the location should not interfere with the ion source. Also, an extreme location such as that of 106″ can be subject to damage by energetic neutrals that result from energetic ions being reflected from sputter target 103. Within the limits of these practical considerations, changing the angle of the deposition substrate relative to the sputter target, again assuming the substrates are tangent to the same sphere, will result in essentially the same tradeoff between deposition rate and uniformity that was described for a parallel substrate-target configuration in FIGS. 1 through 6.

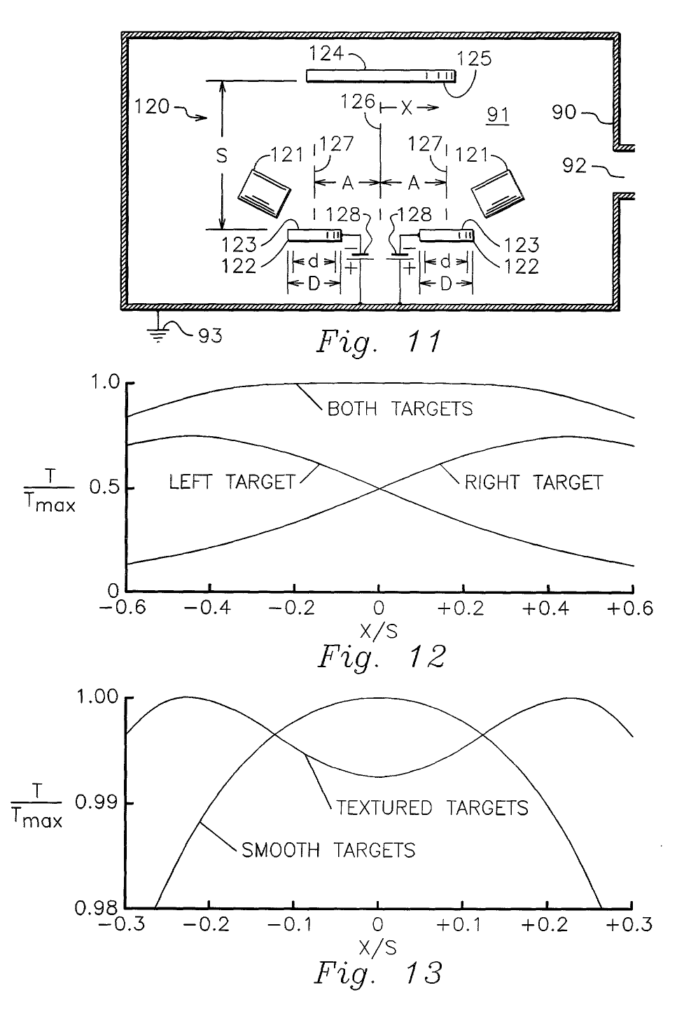

Referring now to FIG. 8, a prior-art deposition apparatus is shown. Except for the addition of shaper 111 between sputter target 103 and deposition substrate 106A, and the rotation of substrate 106A and its surface 107A about the axis 112, it is similar to the prior-art apparatus shown in FIGS. 1 and 4. A top view of the apparatus shown in FIG. 8 is shown in FIG. 9. The contour of the shaper shown in the top view of FIG. 9 is experimentally or analytically selected to obtain a more uniform deposited film by intercepting some of the sputtered material from sputter target 103. The ideal uniformity obtained in this manner is shown in FIG. 10. Compared to the prior-art apparatus shown in FIGS. 1 and 4, the use of a shaper together with substrate rotation permits a larger region of uniform film thickness to be deposited. There are, however, shortcomings. The use of substrate rotation, as with any mechanical motion, tends to generate particulates, which can reduce the production yield. Also, mechanical motion tends to increase both cost and required maintenance. In addition, the contour of the shaper can be optimized for only one operating condition, and changes in sputter-target texture, for example, will cause departures from the optimized condition, hence departures from uniformity.

Another technique that could be used to deposit a uniform film is described in the aforementioned U.S. Pat. No. 6,197,164 B1—Pinarbasi, in which the shaper (called a flux regulator) is moved and the substrate is held fixed. Although this approach can presumably be adaptive in that it can adjust to the change in deposition caused by texturing of the target, it still has the shortcoming of mechanical motion of the shaper.

In the deposition of layered films, it is customary to mechanically move targets to change the material being deposited. Again, mechanical motion is undesirable because it tends to generate particulates, increase cost, and increase required maintenance.

As was mentioned above, the sputtering distributions given above should be considered exemplar of those actually encountered in practical applications of the prior art. At the same time, the equations given are not only qualitatively correct, they are often reasonable approximations from a quantitative viewpoint. They are, in fact, often used for initial design of ion-beam deposition apparatus, with final adjustments made after experimental tests.

### DESCRIPTION OF THE PREFERRED EMBODIMENTS

A preferred embodiment of the present invention is set forth in FIG. 11. The sputter deposition is carried out in evacuated volume 91 enclosed by vacuum chamber 90. The chamber is pumped through port 92 to reach the operating pressure, as well as to maintain that pressure during deposition. The evacuated chamber is usually electrically connected to earth ground 93. Sputter deposition apparatus 120 uses two ion sources 121. The ions (not shown) strike two sputter targets 122, or more specifically the surfaces 123 of these targets. The targets are stationary, i.e., immobile or non-moving during the sputter deposition process.

In the preferred embodiments, ion sources 121 are low-energy ion sources that generate effluxes of low-energy ions, i.e., effluxes in which the ion energies are 50 eV or less, as described in our copending application Ser. No. 09/471,662, filed Dec. 23, 1999. As also described in this copending application, there are several types of low-energy ion sources that might be used. One possibility is a gridded ion source operated with the grids removed. Another possibility is the closed-drift source described by Zhurin, et al., in Plasma Sources Science & Technology, Vol. 8, beginning on page R1. Another, and more preferred source, is the end-Hall ion source described in the aforesaid U.S. Pat. No. 4,862,032—Kaufman, et al.

Because the energies of the ions in the ion effluxes are at or below the sputter threshold, it is not necessary to direct all of the ions at the sputter target surfaces to obtain deposited films that are free of contamination. For sputtering of target surfaces 123 to take place, however, targets 122 must be biased negative of ground, which is defined as the potential of the surrounding vacuum chamber 90, which in turn is usually at earth ground. This negative bias is provided by power supply 128. Material sputtered from the target surfaces is deposited on substrate 124, or more specifically, surface 125 of the substrate. The ions gain energy as they approach the negative targets, thereby attaining energies substantially exceeding the sputter threshold. The relative ion currents generated by the two ion sources and striking two targets 122 and the relative biases of these targets are controlled so that the two targets are sputtering sources of equal strength. There is distance S between the planes of the sputter target surfaces and the surface of the deposition substrate. Sputter targets 122 have diameters D, with sputtering confined to a smaller diameter d of surfaces 122. Because of the low ion energy, there is no need for the ions to be confined to only surfaces 122, and the diameter d can approach the size of diameter D.

Ion sources 121 in apparatus 120 are shown located on either side of apparatus centerline 126. The specific locations of ion sources 121 are not important as long as adequate ion current reaches target surfaces 123 with reasonable current-density profiles at these surfaces, and as long as sputtered material is not intercepted between the targets and the substrate. Target centerlines 127 of targets 123 are located distances A on either side of apparatus centerline 126, with distances A selected to give a region, on substrate surface 125 near apparatus centerline 126 and in the plane of centerlines 126 and 127, a high degree of deposition uniformity.

Refer now to FIG. 12, the sputter contribution from the left target to the deposition thickness T on substrate surface 125 was calculated from equation (4) and is shown as a function of distance X from the apparatus centerline 126, with both expressed in non-dimensional terms (T/Tₘₐₓ and X/S) for generality. The contribution from the left target is a maximum at the location of the left source, X/S=−0.44. The second derivative with respect to distance, d²T/dX², is a minimum at X/S=−0.44, increases with increasing X/S, passes through zero at about X/S=0, and becomes positive for values of X/S>0. The sputter contribution from the right target to the deposition thickness on substrate surface 125 is the mirror image of that from the right target. In general terms, the region of uniformity near X/S=0 was obtained by locating the inflection points, d²T/dX²=0, of the distributions from the two sources at X/S=0, and letting the positive and negative curvatures of the two curvatures balance each other on the two sides of X/S=0, as shown by the curve for both targets. These inflection points were calculated numerically from equation (4).

More specifically, the calculation was made for targets where d/S=0.5. Further, in order to show a tolerance for texturing, the locations of the sources at X/S=±0.44 was selected as a compromise between n=0 and n=1, and because of the low initial mean ion energy of the order of 10 electron-volts compared to the target bias of several hundred volts, the angular offset ø of the sputter distribution due to texturing is assumed to be effectively zero.

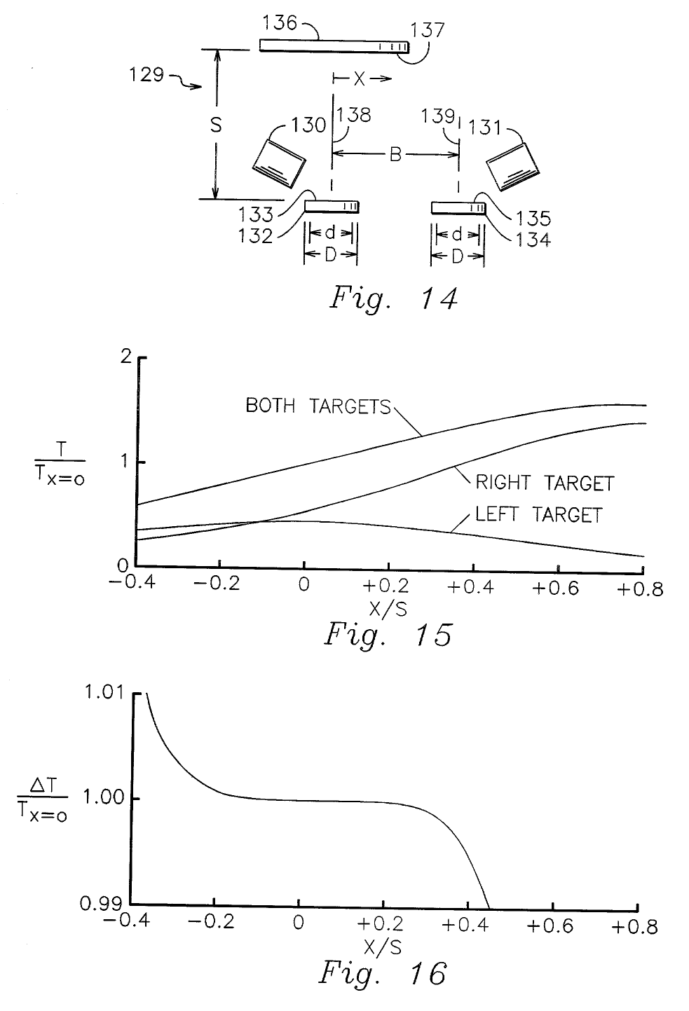

The thickness distributions for smooth targets (n=0) and textured targets (n=1) are shown in an enlarged view of the center of FIG. 12, which is shown in FIG. 13. A substantial region, from X/S<−0.2 to X/S>0.2, shows a uniformity within ±1 percent, with or without target texturing. The large region of uniformity is noteworthy as well as the tolerance to texturing. Of particular interest is that both the large region and the tolerance were obtained without mechanical motion of any kind.

A region of uniform deposition was demonstrated using the embodiment of this invention shown in FIG. 11. A region of linearly varying thickness is obtained with the embodiment shown in FIG. 14. Ion-beam deposition apparatus 129 uses two low-energy ion sources 130 and 131, typically of the end-Hall type. The low-energy ion beams (not shown) strike two sputter targets 132 and 134, with exposed surface 133, and 135. Because the energies of the ions in the ion beams are again at or below the sputter threshold, it is not necessary to direct all of the ions at the sputter target surfaces. Material sputtered from target surfaces 133 and 135 is deposited on substrate 136, or more specifically, surface 137 of that substrate. This sputtering results from a negative bias of targets 132 and 134 relative to ground, which is normally defined as the potential of the surrounding vacuum chamber (not shown) . The ions gain energy as they approach the negative targets, thereby attaining energies substantially exceeding the sputter threshold. There is distance S between the planes of the sputter target surfaces and the surface of the deposition substrate. Sputter targets 132 and 134 have diameters D, with sputtering confined to a smaller diameter d of surfaces 133 and 135. Because of the low ion energy, there is no need for the ions to be confined to only surfaces 133 and 135, and diameter d can approach the size of diameter D.

The specific locations of ion sources 130 and 131 in FIG. 14 are not important as long as adequate ion current reaches target surfaces 133 and 135 with reasonable current-density profiles at these surfaces, and as long as sputtered material is not intercepted between the targets and the substrate. Centerline 138 is the centerline of target 132 as well as the origin of the distance coordinate X. Centerline 139 of target 134 is located at distance B from centerline 138, with distance B and the relative sputtering strengths from targets 132 and 134 selected to give a linear variation in thickness for a deposited film in the substrate region near centerline 138.

Targets were again used with diameters d=0.5S. The maximum positive value of second derivative with respect to distance, d²T/dx², was calculated numerically from equation (5) and is located at a distance of 0.82 S from the center of the target, with distance expressed in terms of the substrate-target spacing S. Target 134 was therefore placed with its centerline 139 at a distance B equal to 0.82 S from centerline 138 of target 132. The centerline increases with increasing X/S, passes through zero at about X/S=0, and becomes positive for values of XIS>0. To balance the maximum positive second derivative with respect to distance of deposition from target 134 with the maximum negative second derivative with respect to distance of deposition from target 132, which is at X=0, the sputtering strength from target 132 was made 32 percent of the sputtering strength of target 134, as the result of numerical calculations of second derivatives from both targets using equation (5). With the second derivatives, d²T/dX², canceled, the first derivative, dT/dX, from target 132 was zero at X=0, and the only significant variation near X=0 was the first derivative from target 134.

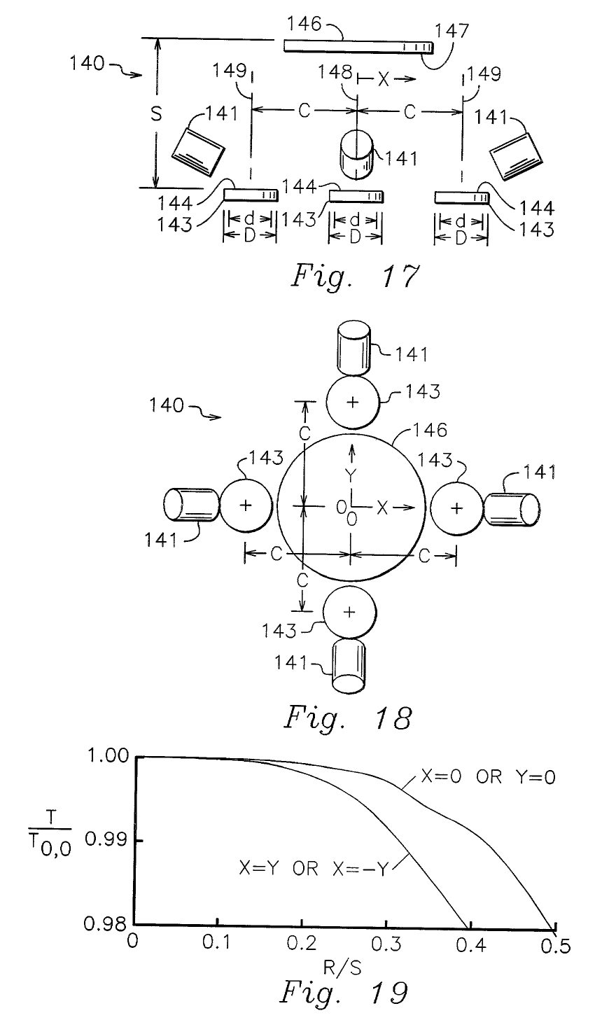

The contributions from the two sputter targets, as well as the sum of those contributions, are shown in FIG. 15. The sum of the contributions is quite linear in the vicinity of X=0. The linearity in this region is shown better in FIG. 16, in which the departure ΔT from the slope at X=0 is shown on an enlarged vertical scale. It is evident from FIG. 16, that a constant first derivative, dT/dX, can be maintained within approximately ±1 percent of mean thickness from X/S ˜−0.4 to X/S˜0.4, while the film thickness varies in thickness by a factor of more than two.

FIGS. 11 and 14 both show apparatus embodiments for control of deposition thickness, one with a uniform thickness and one with a linear variation in thickness. But both are limited to regions near the intersection of the plane passing through both target centerlines with the plane of the substrate. A region of uniform deposition thickness is obtained over a more substantial area of the deposition substrate using the embodiment shown in FIGS. 17 and 18.

Ion-beam deposition apparatus 140, shown in a side view in FIG. 17 and a top view in FIG. 18, uses four low-energy ion sources 141, typically of the end-Hall type. The low-energy ion beams (not shown) strike four sputter targets 143, or more specifically the surfaces 144 of these targets. Because the energies of the ions in the ion beams are at or below the sputter threshold, it is not necessary to direct all of the ions at the sputter target surfaces. Material sputtered from the target surfaces is deposited on substrate 146, or more specifically, surface 147 of the substrate. This sputtering results from a negative bias of targets 143 relative to ground, which is normally defined as the potential of the surrounding vacuum chamber (not shown). The ions gain energy as they approach the negative targets, thereby attaining energies substantially exceeding the sputter threshold. The relative beam currents striking targets 143 and the relative biases of these targets are such that the four targets are sputtering sources of equal strength. There is distance S between the planes of the sputter target surfaces and the surface of the deposition substrate. Sputter targets 143 have diameters D, with sputtering confined to a smaller diameter d of surfaces 144. Because of the low ion energy, there is no need for the ions to be confined to only surfaces 144, and the diameter d can approach the size of diameter D.

Ion sources 141 in apparatus 140 are shown at four equally spaced locations relative to apparatus centerline 148. The specific locations of ion sources 141 are not important as long as sufficient ion current reaches target surfaces 144 with reasonable current-density profiles at these surfaces, and as long as sputtered material is not intercepted between the targets and the substrate. Target centerlines 149 of targets 143 are located distances C in four directions from apparatus centerline 148, with distances C selected to give a region, extending in both X and Y direction, on substrate surface 147 near apparatus centerline 148, with a high degree of deposition uniformity.

The methodology used for areal uniformity was to select a target distance from apparatus centerline 148 such that the second derivative of deposition thickness with distance was of equal magnitude, but opposite sign, in orthogonal directions. Considering the particular target farthest to the left in FIG. 18, the second derivative in the Y direction, d²T/dY², will always be negative. The second derivative in the X direction, d²T/dx², varies from negative values for small values of the distance C to positive values at larger values of C. For the target sizes used, d=0.5 S, a value of C equal to 0.82 S satisfies the condition

d²T/dY²=−d²T/dX². (5)

Referring now to FIG. 19, the sputter contributions from all four targets to the deposition thickness T on substrate surface 147 is shown as a function of radius R/S, where R is the radius from the apparatus centerline 148 and is defined in the customary manner (R=(X²+Y²)^{½}) . The maxima are found where X=0 or Y=0. The deposition minima are of interest because they limit the uniformity at a given radius and are found at given values of R/S where X=Y or X=−Y. Even at the minima for a given radius, however, a uniformity within ±1 percent can be obtained for values of R/S≦0.4.

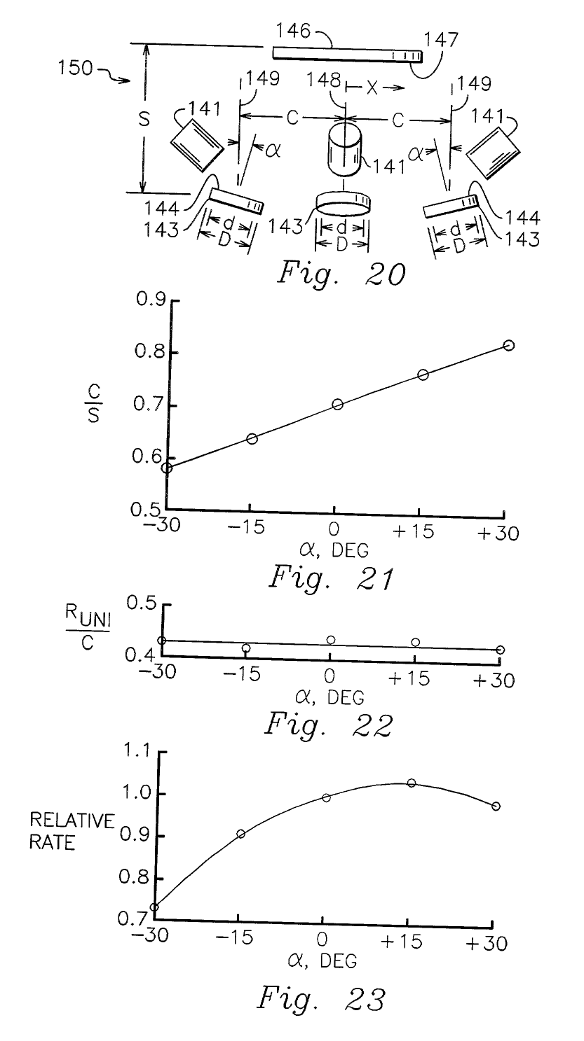

Referring now to FIG. 20, apparatus 150 is an alternate embodiment of the present invention that differs from apparatus 140 shown in FIGS. 17 and 18 in two particulars. First, small targets (d/S≈0) were assumed. Second, the targets are at an angle α relative to a coplanar location. In FIG. 21, the value of C/S is shown as a function of the angle α, where C is the value that satisfies equation (5) for that angle. For an angle of zero in FIG. 21, C/S=0.71. This differs quantitatively but not qualitatively from the C/S=0.82 for apparatus 140 in FIGS. 17 and 18. This difference results from d/S˜0 for apparatus 150, but d/S=0.5 for apparatus 140.

In FIG. 22, the ratio R_{UNI}/C, is seen to be nearly constant over the range of angle α investigated. The radius R is again defined as (X²+Y²)^{½}), with X and Y again defined in FIG. 18. The radius R_{UNI} is defined as the maximum radius over which the variation in film thickness is less than or equal to ±1 percent. Both the maximum and minimum thickness to determine R_{UNI} can be found along the loci of X=Y or X=−Y as described in connection with FIGS. 18 and 19.

Comparing FIGS. 21 and 22, it is evident that, for a given radius of uniform deposition R_{UNI}, S will be a function of angle α, but C will not. From FIG. 22, R_{UNI}/C is approximately constant regardless of α, so that the specification of R_{UNI} will essentially result in the specification of C. With both R_{UNI} and C specified, FIG. 21 shows that S will be a function of α.

Referring now to FIG. 23, the relative rate of deposition is plotted as a function of angle α, with the rate normalized to unity at α=0. There is little change in deposition rate for α from 0 to +30 degrees, but there is a significant drop in rate as the angle decreases below zero.

In summary of FIGS. 20 through 23, there is no qualitative departure from the results shown in FIGS. 17 through 19 when the targets are positioned at an angle relative to the previous coplanar locations.

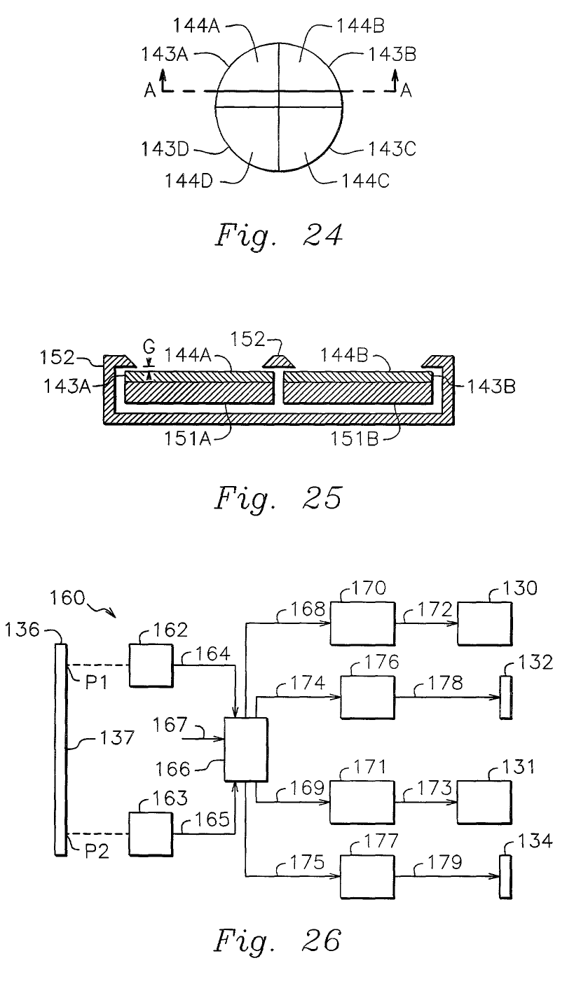

An alternate embodiment of the present invention is presented in FIGS. 24 and 25. In the previous embodiments, multiple sputter targets were used to control the thickness distribution of a deposited film. In FIGS. 24 and 25, multiple sputter targets are used to generate a graded, alloyed, composite, or layered deposition without mechanical motion of the targets. In FIG. 24 the top view is shown of a compound or multiple target in which sputter target 143 is divided into four targets, 143A, 143B, 143C, and 143D, with the target surface 144 divided into corresponding target surfaces 144A, 144B, 144C, and 144D. Such a target might be used in apparatus 140 in FIGS. 17 and 18. The sputter target in FIG. 24 could also be used with a single low-energy ion source.

The four target segments in FIG. 24 may be separate and distinct target materials, separately biased to control sputtering therefrom. A cross section along section A-A of the target shown in FIG. 24 is shown with additional detail in FIG. 25. Each target segment rests on a corresponding target support, e.g., target segment 143A on target support 151A, target segment 143B on target support 151B, etc. Using means known to those skilled in the art, each target segment is in thermal and electrical contact with the corresponding target support, and the target supports are cooled to remove the energy of the bombarding ions. Except for the surfaces 144A, 144B, etc., which are exposed for ion sputtering, the target segments are all enclosed with shield 152. Also using means known to those skilled in the art, shield 152 is located close to surfaces 144A and 144B, see gap G in FIG. 25. Gap G is approximately equal to or less than the plasma sheath thickness at the target to prevent the plasma from penetrating between the shield and the target surfaces, thereby confining the sputtering to the target surfaces not covered by the shield.

As an example of the use of the multiple targets shown in FIGS. 24 and 25, targets 143A and 143C could be made of one material, while targets 143B and 143D could be made of another. A layered deposition could be obtained by first biasing targets 143A and 143C to deposit a layer of the one material, then removing biases from those targets and biasing targets 143B and 143D to deposit a layer of the other material. Alternating the biases on pairs of targets in this manner, a layered deposit can be made without any mechanical motion of targets. Further, a graded or gradual transition from one layer to the next can be obtained by gradually decreasing the negative bias to one pair of targets as the negative bias is gradually increased to the other pair. Gradual transitions from one layer to the next can again be accomplished without mechanical motion of the targets.

The use of multiple targets arranged in the configuration of opposite quadrants, as shown in FIG. 24, would permit shifting from one target material to another without significantly shifting the centroid of sputtering production. That is, the centroid would remain near the center of the overall circular shape regardless of the material being deposited. This means that a configuration optimized for a deposition distribution property, such as uniformity, with one material would, to the first approximation, be optimized for the same deposition property in the other material. Second-order effects can be accounted for with small adjustments in target location, angle, or operating parameters.

### Other Embodiments

The preceding discussions have assumed that the material deposited on the substrates is the same as the target material. Those skilled in the art will recognize that other possibilities exist. For example, the target could be aluminum, and, through reactive deposition, the deposited film could be alumina. The reaction with oxygen into alumina could be the result of background oxygen in the vacuum chamber in which the sputter deposition is taking place, or it could be the result of an oxygen ion beam directed at the deposition substrate.

In a similar manner, the negative bias on a sputter target was implied, by lack of counterexample, to be direct-current. Those skilled in the art will readily recognize that the use of a negative bias in the form of pulses could reduce the likelihood of arcing, and thereby give an increased yield of undamaged films on substrates. Either a radiofrequency bias or a high-frequency pulsed bias, with small positive potentials in both cases to collect electrons and larger negative potentials to cause sputtering, could be used with insulating targets.

The preceding example of four targets arranged in four quadrants of a circular shape (FIG. 24) works well with layered depositions with alternating composition using two deposition materials. Layered deposition with more materials could be obtained with multiple targets arranged in six or more segments of a circle. Multiple targets could also be arrangements of triangles, rectangles, or other polygons, rather than segments of a circular shape.

Mechanical motion has generally been avoided, and correctly so because it can generate particulates, increase equipment cost, and increase required maintenance, thereby increasing production cost and/or reducing the useful production output. There are, however, applications where objectives such as extreme uniformity, or the need to operate with highly textured sputter targets, make some mechanical motion desirable. For example, a sputter deposition system that makes a moderately uniform deposition could, with the addition of deposition substrate rotation, make an even more uniform deposition.

The preferred embodiments of this invention have used low-energy ion sources, typically of the end-Hall type. As an alternate embodiment, ion sources that generate beams of energetic ions, with the ion energies well above the sputtering threshold, could also be used. Referring for example to FIG. 11, ion sources 121 could be gridded sources that generate beams of energetic ions. Control of the relative sputtering from two or more targets would be obtained by controlling the energies and/or ion currents in the ion beams generated by the respective ion sources. In order to deposit films that are essentially free of contamination at the higher ion energies, almost all of the energetic ions must be directed at target surfaces 123. Although targets 122 could be biased, there is no significant advantage of doing so when energetic ion beams are used, and a grounded potential (the potential of surrounding vacuum chamber 90) would be more typical. In this case, the potential of power supply 128 would be zero. The embodiment shown in FIG. 11 could, with sources that generate energetic beams of ions and either grounded or biased targets, still be used to deposit uniform films over a substantial region, as shown in FIG. 12 and in FIG. 13 for “Smooth targets.” Because the texturing of the target would be more offset from the target surface normal with energetic ion beams, the thickness distribution shown in FIG. 13 for “Textured targets” would show a larger departure from uniformity.

In a similar manner, the configurations shown in FIGS. 14, 17, 18, and 20 could also be used with ion sources that generate energetic beams of ions and either grounded or biased targets. The target configuration shown in FIGS. 24 and 25 could, with the omission of shield 152, be used with an energetic ion beam, but the control of relative sputtering from different targets in the same energetic ion beam would be more restricted than with low-energy ion sources. That is, the sputtering of a target could be increased by a negative bias of that target, but the sputtering could not be reduced to near zero by removing that bias. (It may appear that the sputtering from a target could be reduced to near zero by a sufficiently large positive bias of that target. But a large positive bias on the target raises the plasma potential in the entire ion beam, resulting in the beam expanding to cover adjacent hardware and greatly increase contamination by striking that hardware.)

Process control can be passive in that operating parameters can be set at predetermined values that have been found in previous operation to give the desired results. High precision may require that the process control be active. For an apparatus similar to that shown in FIG. 14, active control 160 is indicated schematically in FIG. 26 for the film being deposited on surface 137 of substrate 136. Sensors 162 and 163 monitor the film thickness at points P1 and P2 on surface 137. The sensing could be optical, in which case the measurement could be of the transmission, reflection, absorption, or polarization properties, or a combination thereof using interferometric or ellipsometric techniques to determine the film thickness. Acousto-optic techniques and sensing techniques based on magnetic, resistive, density or other physical property of the film could also be used. The film thickness could also be inferred from a mass measurement, in which case a quartz crystal monitor could either be incorporated into the substrate or located near the substrate, i.e., close enough to be representative of the film thickness proximal to that measurement. Using one of these thickness sensing techniques, or some other technique known to those skilled in the art, the thicknesses at or near points P1 and P2 are monitored by sensors 162 and 163. Signals 164 and 165 from these sensors are transmitted to comparator 166, which compares these signals with programmed values 167 to determine appropriate control signals 168 and 169 to transmit to ion-source controllers 170 and 171, which in turn, controls operating parameters 172 and 173 that are transmitted to ion sources 130 and 131, thereby obtaining desired operation from these ion sources. Appropriate control signals 174 and 175 are also sent to bias power supplies 176 and 177, which in turn send negative biases 178 and 179 to targets 132 and 134. As an example of how the process is controlled, if the thickness at point P1 located on surface 137 close to ion source 130 is larger than it should be in comparison to the thickness at point P2 located on surface 137 close to ion source 131, comparator 166 transmits signals to power supply 170 to increase the ion current in the efflux of ion source 130 relative to that of ion source 131. Signals may also be transmitted to power supply 176 to increase the negative bias 178 of target 132 near ion source 130 relative to that of target 134 near ion source 131. It should be apparent that control could be only by controlling the relative ion currents in the effluxes from the two ion sources, or only by controlling the relative negative biases of the two targets, or by controlling the relative ion currents and relative negative biases simultaneously. It should be apparent that more than two sensors could be used with additional ion sources and targets. It should also be apparent that multiple targets of several materials could be used with programmed values 167 that change with time to produce a high-precision layered or other spatially-varying structure. While a low-energy ion source was assumed in the preceding discussion, a similar control could be used with more energetic ion sources in which both the ion currents and ion energies could be varied to achieve control.

As described by Kaufman, et al., in the brochure, Characteristics, Capabilities, and Applications of Broad-Beam Ion Sources, Commonwealth Scientific Corporation, Alexandria, Va. (1987), incorporated herein by reference, it is possible to have variations in deposition processes. A reactive gas may be introduced into the vacuum chamber where deposition is taking place. The reactive gas can then combine with the materials being deposited for reactive deposition. It is also possible to use ion-assisted deposition where inert gas ions bombard the substrate as the film is being deposited giving enhanced properties such as increased density, increased adhesion, and stress control. The ions in ion-assisted deposition can also be reactive, so that the material from which the ions are made is incorporated in the deposited film. These variations in the deposition process can also be used with the present invention.

While particular embodiments of the present invention have been shown and described, and various alternatives have been suggested, it will be obvious to those of ordinary skill in the art that changes and modifications may be made without departing from the invention in its broadest aspects. Therefore, the aim in the appended claims is to cover all such changes and modifications as fall within the true spirit and scope of that which is patentable.

We claim:

1. A sputtering apparatus for use in a vacuum chamber comprising:
ion source means for generating ions with said ions leaving said ion source means in the form of an ion efflux having an energy of about 50 eV or less;
at least one deposition substrate; and
a plurality of stationary sputter targets comprised of a material, upon which said ion efflux is directed, wherefrom said material is sputtered, with means for applying to each of said targets a negative bias relative to ground, with said targets located relative to said substrate and said biases of said targets controlled so as to generate a deposition of said material on said substrate having a thickness wherein said thickness has a predetermined distribution.

2. Apparatus in accordance with claim 1 further comprising a plurality of sensors for providing measurements of said thickness of said deposition at a plurality of locations on or near said substrate and wherein comparisons of said measurements are used to control said biases of said targets during deposition.

3. A sputtering apparatus for use in a vacuum chamber comprising:
ion source means for generating ions with said ions leaving said ion source means in the form of an ion efflux having an energy of about 50 eV or less;
at least one deposition substrate; and
a plurality of stationary sputter targets comprised of a plurality of materials, upon which said ion efflux is directed, wherefrom material is sputtered, with a plurality of means for applying to said targets negative biases relative to ground, with said biases controlled such that a predetermined composition of said materials from said targets is deposited on said substrate.

4. A sputtering apparatus for use in a vacuum chamber comprising:
ion source means for generating ions with said ions leaving said ion source means in the form of an ion efflux having an energy of about 50 eV or less;
at least one deposition substrate; and
a plurality of stationary sputter targets comprised of a plurality of materials, upon which said ion efflux is directed, wherefrom material is sputtered, with a plurality of means for applying to said targets negative biases relative to ground, with said biases controlled in a time-sequential manner such that layers of different compositions of said materials are deposited sequentially on said substrate.

5. A sputtering apparatus for use in a vacuum chamber comprising:
ion source means for generating ions with said ions leaving said ion source means in the form of an ion efflux having an energy of about 50 eV or less;
at least one deposition substrate; and
a plurality of stationary sputter targets comprised of a plurality of materials, upon which said ion efflux is directed, wherefrom material is sputtered, with a plurality of means for applying to said targets negative biases relative to ground, with said biases varied in a time-varying manner so that the deposit on said substrate varies in a continuous manner from an initial composition comprised of respective said target materials to a following and different composition comprised of said materials.

6. An ion-beam deposition apparatus for operation in a vacuum chamber comprising:
a plurality of ion-source means for generating a plurality of ion beams, wherein each ion beam has an ion energy and an ion current with said ion energy and ion current independently controllable;
at least one deposition substrate; and
a plurality of stationary sputter targets comprised of a material, upon which said ion beams are directed, wherefrom said material is sputtered, with said targets located relative to said substrate and said ion energies and said ion currents of said ion beams controlled so as to generate a deposition of said material on said substrate having a thickness wherein said thickness has a predetermined distribution.

7. Apparatus in accordance with claim 6 further comprising a plurality of sensors for providing measurements of said thickness of said deposition at a plurality of locations on or near said substrate and wherein comparisons of said measurements are used to control said ion energies and said ion currents during deposition.

8. An ion-beam deposition apparatus for operation in a vacuum chamber comprising:
a plurality of ion-source means for generating a plurality of ion beams, wherein each ion beam has an ion energy and an ion current with said ion energy and ion current independently controllable;
at least one deposition substrate; and
a plurality of stationary sputter targets comprised of a plurality of materials, upon which said ion beams are directed, wherefrom material is sputtered, with said ion energies and said ion currents of said ion beams controlled in a time-sequential manner such that layers of different compositions of said materials are deposited sequentially on said substrate.

9. An ion-beam deposition apparatus for operation in a vacuum chamber comprising:
a plurality of ion-source means for generating a plurality of ion beams, wherein each ion beam has an ion energy and an ion current with said ion energy and ion current independently controllable;
at least one deposition substrate; and
a plurality of stationary sputter targets comprised of a plurality of materials, upon which said ion beams are directed, wherefrom material is sputtered, with said ion beams controlled in a time-varying manner such that the deposit on said substrate varies in a continuous manner from an initial composition comprised of respective said target materials to a following and different composition comprised of said materials.

10. A sputtering apparatus for use in a vacuum chamber comprising:
a plurality of ion source means for generating ions, each with said ions leaving said ion source means in the form of an ion efflux having an energy of about 50 eV or less and wherein said efflux has an ion current that is independently controllable;
at least one deposition substrate; and
a plurality of stationary sputter targets, upon which said ion effluxes are directed, wherefrom material is sputtered, with means for applying to each of said targets a negative bias relative to ground, with said targets located relative to said substrate and said ion currents of said ion sources and said negative biases of said targets controlled so as to generate a deposition of said material on said substrate having a thickness wherein said thickness has a predetermined distribution.

11. Apparatus in accordance with claim 10 further comprising a plurality of sensors for providing measurements of said thickness of said deposition at a plurality of locations on or near said substrate and wherein comparisons of said measurements are used to control said ion currents of said sources and said biases of said targets during deposition.

12. A sputtering apparatus for use in a vacuum chamber comprising:
a plurality of ion source means for generating ions, each with said ions leaving said ion source means in the form of an ion efflux having an energy of about 50 eV or less and wherein said efflux has a total ion current that is independently controllable;
at least one deposition substrate; and
a plurality of stationary sputter targets comprised of a plurality of materials, upon which said ion efflux is directed, wherefrom material is sputtered, with means for applying to each of said targets a negative bias relative to ground, with said ion currents of said ion sources and said negative biases of said targets controlled so as to generate a predetermined composition of the deposition on said substrate comprised of respective materials or combinations of materials from said targets.

13. A sputtering apparatus for use in a vacuum chamber comprising:
a plurality of ion source means for generating ions, each with said ions leaving said ion source means in the form of an ion efflux having an energy of about 50 eV or less and wherein said efflux has a total ion current that is independently controllable;
at least one deposition substrate; and
a plurality of stationary sputter targets comprised of a plurality of materials, upon which said ion efflux is directed, wherefrom material is sputtered, with means for applying to each of said targets a negative bias relative to ground, with said ion currents of said ion sources and said biases of said targets controlled so as to generate a predetermined layered deposition on said substrate with respective layers comprised of respective materials or combinations of materials from said targets.

14. A sputtering apparatus for use in a vacuum chamber comprising:
a plurality of ion source means for generating ions, each with said ions leaving said ion source means in the form of an ion efflux having an energy of about 50 eV or less and wherein said efflux has a total ion current that is independently controllable;
at least one deposition substrate; and
a plurality of stationary sputter targets comprised of a plurality of materials, upon which said ion efflux is directed, wherefrom material is sputtered, with means for applying to each of said targets a negative bias relative to ground, with said ion currents of said ion sources and said biases of said targets controlled so as to generate a predetermined graded deposition on said substrate with said deposition changing from one composition comprised of respective said target materials to another composition comprised of said materials.

15. A method for sputtering material within a vacuum chamber, the method comprising the steps of:
(a) providing an ion source means capable of generating ions with said ions leaving said ion source means in the form of an ion efflux having an energy of about 50 eV or less;
(b) providing at least one deposition substrate;
(c) providing a plurality of stationary targets;
(d) biasing each of said targets negative relative to ground;
(e) directing said ion efflux upon said targets so as to sputter material therefrom; and
(f) locating said substrate relative to said targets and controlling said biases so as to deposit upon said substrate a film of said material having a thickness with a predetermined thickness distribution.

16. A method in accordance with claim 15 comprising the further steps of:
(g) locating a plurality of sensors to provide measurements of said thickness at a plurality of locations on or near said substrate;
(h) making comparisons of said measurements of said thickness; and
(i) using said comparisons to control said biases of said substrates.

17. A method for sputtering material within a vacuum chamber, the method comprising the steps of:
(a) providing an ion source means capable of generating ions with said ions leaving said ion source means in the form of an ion efflux having an energy of about 50 eV or less;
(b) providing at least one deposition substrate;
(c) providing a plurality of stationary targets comprised of a plurality of materials;
(d) biasing each of said targets negative relative to ground;
(e) directing said ion efflux upon said targets so as to sputter material therefrom; and
(f) controlling said biases so as to deposit on said substrate a film comprised of a predetermined composition of said materials.

18. A method for sputtering material within a vacuum chamber, the method comprising the steps of:
(a) providing an ion source means capable of generating ions with said ions leaving said ion source means in the form of an ion efflux having an energy of about 50 eV or less;
(b) providing at least one deposition substrate;
(c) providing a plurality of stationary targets comprised of a plurality of materials;
(d) biasing each of said targets negative relative to ground;
(e) directing said ion efflux upon said targets so as to sputter material therefrom; and
(f) controlling said biases in a time-sequential manner so layers of different compositions of said materials are deposited sequentially on said substrate.

19. A method for sputtering material within a vacuum chamber, the method comprising the steps of:
(a) providing an ion source means capable of generating ions with said ions leaving said ion source means in the form of an ion efflux having an energy of about 50 eV or less;
(b) providing at least one deposition substrate;
(c) providing a plurality of stationary targets comprised of a plurality of materials;
(d) biasing each of said targets negative relative to ground;
(e) directing said ion efflux upon said targets so as to sputter material therefrom; and
(f) controlling said biases in a time-varying manner so that the deposit on said substrate varies in a continuous manner from an initial composition comprised of respective said target materials to a following and different composition comprised of said materials.

20. A method for sputtering material within a vacuum chamber, the method comprising the steps of:
(a) providing a plurality of ion source means capable of generating ions with said ions leaving each of said ion source means in the form of an ion efflux having an energy of about 50 eV or less and wherein said efflux has an ion current that is independently controllable;
(b) providing at least one deposition substrate;
(c) providing a plurality of stationary targets comprised of a material;
(d) biasing each of said targets negative relative to ground;
(e) directing said ion efflux upon said targets so as to sputter said material therefrom and deposit said material on said substrate; and
(f) locating said targets relative to said substrate and controlling said ion currents and said negative biases so as to deposit upon said substrate a film of said material having a thickness with a predetermined thickness distribution.

21. A method in accordance with claim 20 comprising the further steps of:
(g) locating a plurality of sensors to provide measurements of said thickness at a plurality of locations on or near said substrate;
(h) making comparisons of said measurements of said thickness; and
(i) using said comparisons to control said ion currents of said sources and said biases of said substrates.

22. A method for sputtering material within a vacuum chamber, the method comprising the steps of:
(a) providing a plurality of ion source means capable of generating ions with said ions leaving each of said ion source means in the form of an ion efflux having an energy of about 50 eV or less and wherein said efflux has an ion current that is independently controllable;
(b) providing at least one deposition substrate;
(c) providing a plurality of stationary targets composed of a plurality of materials;
(d) biasing each of said targets negative relative to ground;
(e) directing said ion efflux upon said targets so as to sputter material therefrom and deposit said material on said substrate; and
(f) controlling said ion currents and said negative biases so that a predetermined composition of said materials is deposited upon said substrate.

23. A method for sputtering material within a vacuum chamber, the method comprising the steps of:
(a) providing a plurality of ion source means capable of generating ions with said ions leaving each of said ion source means in the form of an ion efflux having an energy of about 50 eV or less and wherein said efflux has an ion current that is independently controllable;
(b) providing at least one deposition substrate;
(c) providing a plurality of stationary targets composed of a plurality of materials;
(d) biasing each of said targets negative relative to ground;
(e) directing said ion efflux upon said targets so as to sputter material therefrom and deposit said material on said substrate; and
(f) controlling said biases and said ion currents in a time-sequential manner such that layers of different compositions of said materials are deposited sequentially on said substrate.

24. A method for sputtering material within a vacuum chamber, the method comprising the steps of:
(a) providing a plurality of ion source means capable of generating ions with said ions leaving each of said ion source means in the form of an ion efflux having an energy of about 50 eV or less and wherein said efflux has an ion current that is independently controllable;
(b) providing at least one deposition substrate;
(c) providing a plurality of stationary targets composed of a plurality of materials;
(d) biasing each of said targets negative relative to ground;
(e) directing said ion efflux upon said targets so as to sputter material therefrom and deposit said material on said substrate; and
(f) controlling said biases and said ion currents in a time-varying manner such that the deposit on said substrate varies in a continuous manner from an initial composition comprised of respective said target materials to a following and different composition of said materials.

25. A method for sputtering material within a vacuum chamber, the method comprising the steps of:
(a) providing a plurality of ion source means capable of generating ions with said ions leaving each of said ion source means in the form of an ion beam having an energy and an ion current that are independently controllable;
(b) providing at least one deposition substrate;
(c) providing a plurality of stationary targets comprised of a material;
(d) directing said ion beams upon said targets so as to sputter said material therefrom and deposit said material on said substrate; and
(e) locating said targets relative to said substrate and controlling said ion energies and said ion currents so as to deposit upon said substrate a film of said material having a thickness with a predetermined thickness distribution.

26. A method in accordance with claim 20 comprising the further steps of:
(g) locating a plurality of sensors to provide measurements of said thickness at a plurality of locations on or near said substrate;
(h) making comparisons of said measurements of said thickness; and
(i) using said comparisons to control said ion currents and said biases.

27. A method for sputtering material within a vacuum chamber, the method comprising the steps of:
(a) providing a plurality of ion source means capable of generating ions with said ions leaving each of said ion source means in the form of an ion beam having an energy and an ion current that are independently controllable;
(b) providing at least one deposition substrate;
(c) providing a plurality of stationary targets comprised of a plurality of materials;
(d) directing said ion beams upon said targets so as to sputter said materials therefrom and deposit said material on said substrate; and
(e) controlling said ion energies and said ion currents in a time-sequential manner such that layers of different compositions of said materials are deposited sequentially on said substrate.

28. A method for sputtering material within a vacuum chamber, the method comprising the steps of:
(a) providing a plurality of ion source means capable of generating ions with said ions leaving each of said ion source means in the form of an ion beam having an energy and an ion current that are independently controllable;
(b) providing at least one deposition substrate;
(c) providing a plurality of stationary targets comprised of a plurality of materials;
(c) directing said ion beams upon said targets so as to sputter said materials therefrom and deposit said material on said substrate; and
(d) controlling said ion energies and said ion currents in a time-varying manner such that the deposit on said substrate varies in a continuous manner from an initial composition comprised of respective said target materials to a following and different composition of said materials.

29. Apparatus in accordance with claims 1 through 5 and 10 through 28 wherein said ion source means comprises an end-Hall ion source.

30. Apparatus in accordance with claims 1 through 28 wherein there is an additional ion source and the additional ion beam from said additional ion source is directed at said substrate.

31. Apparatus in accordance with claims 1 through 28 wherein there is an additional ion source and the additional ion beam from said additional ion source is directed at said substrate and wherein the ions in said additional ion beam react with said material or materials being deposited upon said substrate.

32. Apparatus in accordance with claims 1 through 28 wherein a reactive gas is introduced into said vacuum chamber.
